(19) United States
(12) Patent Application Publication
(10) Pub. No.: US 2012/0170773 A1
(43) Pub. Date: Jul. 5, 2012

(54) AMPLIFIER WITH HIGH-FREQUENCY NOISE REMOVING FUNCTION, MICROPHONE MODULE, AND SENSOR MODULE

(76) Inventors: Yoshikazu Makabe, Osaka (JP); Shuya Yamasaki, Osaka (JP)

(21) Appl. No.: 13/141,293

(22) PCT Filed: Sep. 7, 2010
(86) PCT No.: PCT/JP10/05487

§ 371 Date: Jun. 21, 2011

(30) Foreign Application Priority Data
Jan. 13, 2010 (JP) 2010-004721

(51) Int. Cl. H03F 1/26; H03F 99/00

(52) U.S. Cl. 381/120; 330/149

(57) ABSTRACT

An amplifier 100 with a high-frequency noise removing function according to the present invention includes: an input terminal 101 to which an input signal is input; a ground terminal 102 maintained at a reference potential; a resistor 111 connected to the input terminal; an amplifying circuit 201 configured to amplify and output the input signal input through the resistor; and an output terminal 103 through which an output signal output from the amplifying circuit is output. The amplifying circuit includes a parasitic capacitance 112 configured to be connected to between one terminal of the resistor, the terminal being located on the opposite side of the input terminal, and the ground terminal, and the resistor and the parasitic capacitance constitute a low-pass filter 113.

### TECHNICAL FIELD

The present invention relates to an amplifier with a high-frequency noise removing function, a microphone module, and a sensor module.

### BACKGROUND ART

In recent years, electronic devices, such as mobile phones and notebook computers, which are increasing in functionality and performance are being used in environments in which the electronic devices are constantly exposed to various high-frequency noises, such as electromagnetic waves of TV broadcasting, radio broadcasting, and radars and electromagnetic waves unintentionally generated by operations of the electronic devices based on their functions. Therefore, the high-frequency noises tend to be input to an external terminal of the electronic device. For example, this may cause noises in an audible frequency band and deteriorate a noise performance of the electronic device itself. Here, an important subject is to take care of the high-frequency noises for the electronic devices. Especially, countermeasures for removing the high-frequency noises are required in various modules mounted on most of the electronic devices.

Hereinafter, a module having a countermeasure against the high-frequency noise described in PTL 1 will be explained in reference to FIG. 11. FIG. 11 is a circuit diagram showing the configuration of a conventional sensor module.

A sensor module 500 shown in FIG. 11 includes an input terminal 501, a ground terminal 502, an output terminal 503, a power supply terminal 504, an amplifying circuit 202, a first resistor 211, a first capacitor 212, a second resistor 213, and a second capacitor 214.

An output terminal of the amplifying circuit 202 is connected to one terminal of the first capacitor 212 and the first resistor 211. The other terminal of the first capacitor 212 is connected to the ground terminal 502, and the other terminal of the first resistor 211 is connected to the output terminal 503.

With this configuration, a low-pass filter constituted by the first capacitor 212 the first resistor 211 is realized with respect to the output terminal of the amplifying circuit 202. In a case where the high-frequency noise is input to the output terminal 503, it is attenuated by the low-pass filter constituted by the first capacitor 212 and the first resistor 211. Therefore, the input of the high-frequency noise to the amplifying circuit 202 can be prevented.

The other terminal of the second resistor 213 is connected to the second capacitor 214 and a power supply terminal of the amplifying circuit 202. The other terminal of the second capacitor 214 is connected to the ground terminal 502. The ground terminal 502 is connected to a ground terminal of the amplifying circuit 202.

With this configuration, a low-pass filter constituted by the second resistor 213 and the second capacitor 214 is realized with respect to the power supply terminal 504. In a case where the high-frequency noise is input to the power supply terminal 504, it is attenuated by the low-pass filter constituted by the second resistor 213 and the second capacitor 214. Therefore, the input of the high-frequency noise to the power supply terminal of the amplifying circuit 202 can be prevented.

### CITATION LIST

### Patent Literature

PTL 1: Japanese Laid-Open Patent Application Publication No. 8-184462

### SUMMARY OF INVENTION

### Technical Problem

In the module having the countermeasure against the high-frequency noise as shown in FIG. 11, the countermeasure against the high-frequency noise is prepared for each of the power supply terminal and the output terminal but is not prepared for the input terminal. Therefore, if the high-frequency noise is input to the input terminal, it is input to the inside of the module, and this deteriorates the noise performance of an output signal from the output terminal of the module. Therefore, the countermeasure against the high-frequency noise for the input terminal of the module needs to be prepared.

Here, in order to provide for the input terminal the low-pass filter, which is the same as the low-pass filter provided for each of the power supply terminal and the output terminal as shown in FIG. 11, a high-frequency noise removing capacitor is simply connected to the input terminal. In this case, not only the high-frequency noises but also the input signals may flow to and be attenuated by the high-frequency noise removing capacitor. Thus, the module may not be able to function in accordance with its specifications. Especially, in a case where the input signal is an extremely low voltage, it is necessary to avoid the attenuation of the input signal as much as possible.

The present invention was made to solve the above conventional problems, and an object of the present invention is to provide an amplifier with a high-frequency noise removing function in which a countermeasure against high-frequency noises is prepared for an input terminal thereof, a microphone module, and a sensor module.

### SOLUTION TO PROBLEM

To achieve the above object, an amplifier with a high-frequency noise removing function according to the present invention includes: an input terminal to which an input signal is input; a ground terminal maintained at a reference potential; a resistor having one terminal to which the input terminal is connected; an amplifying circuit configured to amplify and output the input signal input through the resistor; and an output terminal through which an output signal output from the amplifying circuit is output, wherein: the amplifying circuit includes a parasitic capacitance existing to be connected to between the other terminal of the resistor and the ground terminal; and the resistor and the parasitic capacitance constitute a low-pass filter.

In accordance with this configuration, only by effectively utilizing the parasitic capacitance existing in the amplifying circuit and providing the resistor between the input terminal and the amplifying circuit, the parasitic capacitance and the resistor can constitute the low-pass filter. Then, the low-pass filter can remove the high-frequency noise superimposed on the input signal input to the input terminal.

The above amplifier with the high-frequency noise removing function may further include: a positive surge protective diode; and a negative surge protective diode, wherein: an anode electrode of the positive surge protective diode and a cathode electrode of the negative surge protective diode may be connected to the input terminal; and a cathode electrode of the positive surge protective diode and an anode electrode of the negative surge protective diode may be connected to the ground terminal.

In accordance with this configuration, the resistor provided to constitute the low-pass filter, and therefore, the amplifying circuit can be protected from a positive surge voltage or a negative surge voltage.

The above amplifier with the high-frequency noise removing function may further include: a positive surge protective diode; and a negative surge protective diode, wherein: an anode electrode of the positive surge protective diode and a cathode electrode of the negative surge protective diode may be connected to said other terminal of the resistor or an input terminal of the amplifying circuit; and a cathode electrode of the positive surge protective diode and an anode electrode of the negative surge protective diode may be connected to the ground terminal.

In accordance with this configuration, the amplifying circuit can be protected from the positive surge voltage or the negative surge voltage. Moreover, in a case where the capacitance value of the parasitic capacitance necessary for realizing a desired cut-off frequency is inadequate, the capacitance values of the positive surge protective diode and the negative surge protective diode can be effectively utilized.

In the above amplifier with the high-frequency noise removing function, a resistance value R of the resistor and a capacitance value C of the parasitic capacitance may be set so as to satisfy three formulas below:

RC≧1.6×10⁻⁹ (Formula A);

C≦300 [fF] (Formula B); and

R≦10 [kΩ] (Formula C).

In accordance with this configuration, it is possible to realize the low-pass filter which suppresses thermal noises generated by the resistor and has the cut-off frequency necessary to attenuate the high-frequency noise in the GHz band by utilizing the parasitic capacitance.

To achieve the above object, a microphone module according to another aspect of the present invention includes the above amplifier with the high-frequency noise removing function.

To achieve the above object, a sensor module according to yet another aspect of the present invention includes the above amplifier with the high-frequency noise removing function.

### BRIEF DESCRIPTION OF DRAWINGS

FIG. 1 is a circuit diagram showing the configuration of an amplifier with a high-frequency noise removing function according to Embodiment 1 of the present invention.

FIG. 2 is a diagram for explaining utilization of a parasitic capacitance in the amplifier with the high-frequency noise removing function according to Embodiment 1 of the present invention.

FIG. 3 is a diagram showing one example of the parasitic capacitance in the amplifier with the high-frequency noise removing function according to Embodiment 1 of the present invention.

FIG. 4 is a graph for explaining a band of a cut-off frequency of a low-pass filter, the band being necessary to attenuate high-frequency noises in a GHz band.

FIG. 5 is a graph for explaining a relation between a resistance value of the resistor and a capacitance value of the parasitic capacitance, the values being necessary to attenuate the high-frequency noise in the GHz band.

FIGS. 6 are diagrams each showing a configuration example of a low-pass filter and amplifying circuit which can deal with the high-frequency noise of 1 [GHz] simulated as an amplitude modulated signal.

FIGS. 7 are diagrams showing examples of waveforms of major signals of the amplifier with the high-frequency noise removing function shown in FIG. 1.

FIG. 8 is a circuit diagram showing the configuration of the amplifier with the high-frequency noise removing function according to Embodiment 2 of the present invention.

FIG. 9 is a circuit diagram showing the configuration of the amplifier with the high-frequency noise removing function according to Embodiment 3 of the present invention.

FIG. 10 is a diagram showing the configuration of a microphone module configured by using the amplifier with the high-frequency noise removing function according to Embodiment 4 of the present invention.

FIG. 11 is a diagram showing the configuration of a module having a conventional countermeasure against high-frequency noises.

### DESCRIPTION OF EMBODIMENTS

Hereinafter, preferred embodiments of the present invention will be explained in reference to the drawings. In the following explanation and the drawings, the same reference signs are used for the same or corresponding components, and a repetition of the same explanation is avoided.

### Embodiment 1

Configuration of Amplifier with High-Frequency Noise Removing Function

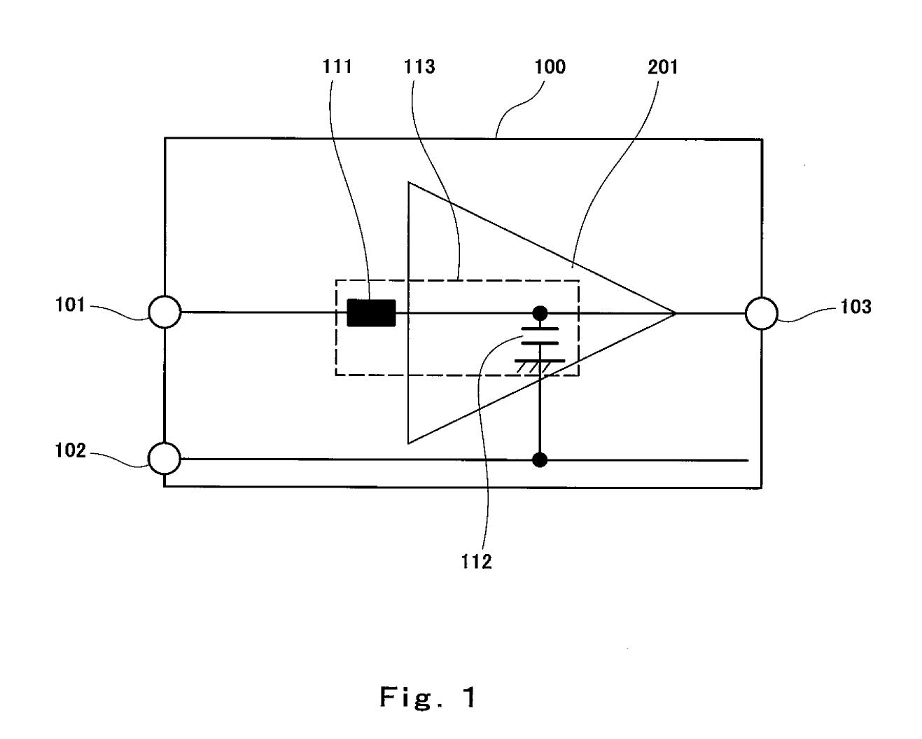

FIG. 1 is a circuit diagram showing the configuration of an amplifier with a high-frequency noise removing function according to Embodiment 1 of the present invention.

An amplifier 100 with a high-frequency noise removing function shown in FIG. 1 is, for example, a preamplifier IC (Integrated Circuit) incorporated in an input stage of a microphone module obtained by modularizing a microphone, such as an electret capacitor microphone, including a capacitive microphone element, or a sensor module obtained by modularizing a capacitance type sensor, such as an acceleration sensor or a pressure sensor. Hereinafter, explanations will be made by using the preamplifier IC of the microphone module as an example.

The amplifier 100 with the high-frequency noise removing function is configured as an integrated circuit of a semiconductor manufacturing process, the integrated circuit including an input terminal 101, a ground terminal 102, an output terminal 103 also used as a power supply terminal, a resistor 111, and an amplifying circuit 201, or is configured as an integrated MEMS (Micro Electro Mechanical Systems) chip including the above components and an electret element. A parasitic capacitance 112 potentially exists on a signal transmission line in the amplifying circuit 201.

The input terminal 101 is connected to one terminal of the resistor 111. The other terminal of the resistor 111 is connected to an input terminal of the amplifying circuit 201 and one end (conductor) of the parasitic capacitance 112. An output terminal of the amplifying circuit 201 is connected to the output terminal 103. Moreover, a ground terminal of the amplifying circuit 201 is connected to the ground terminal 102. The other end (conductor) of the parasitic capacitance 112 is connected to the ground terminal 102.

In the above configuration, the resistor 111 and the parasitic capacitance 112 constitute a low-pass filter 113. The low-pass filter 113 realizes a function of attenuating high-frequency noises input to the input terminal 101. The low-pass filter 113 is configured to let an input signal in an audio frequency band (for example, 20 [Hz] to 20 [kHz]), which is extremely lower than the band of the high-frequency noise, pass therethrough without practically attenuating the input signal.

To obtain a resistance value required in the low-pass filter 113, the resistor 111 is realized by not a wiring resistance potentially existing in the amplifier 100 but an separately-produced resistor. Specifically, the resistor 111 is realized by, for example, a resistor as a discreet product or a diffusion resistance of an impurity diffusion layer (a source electrode, a drain electrode, or the like) of a transistor.

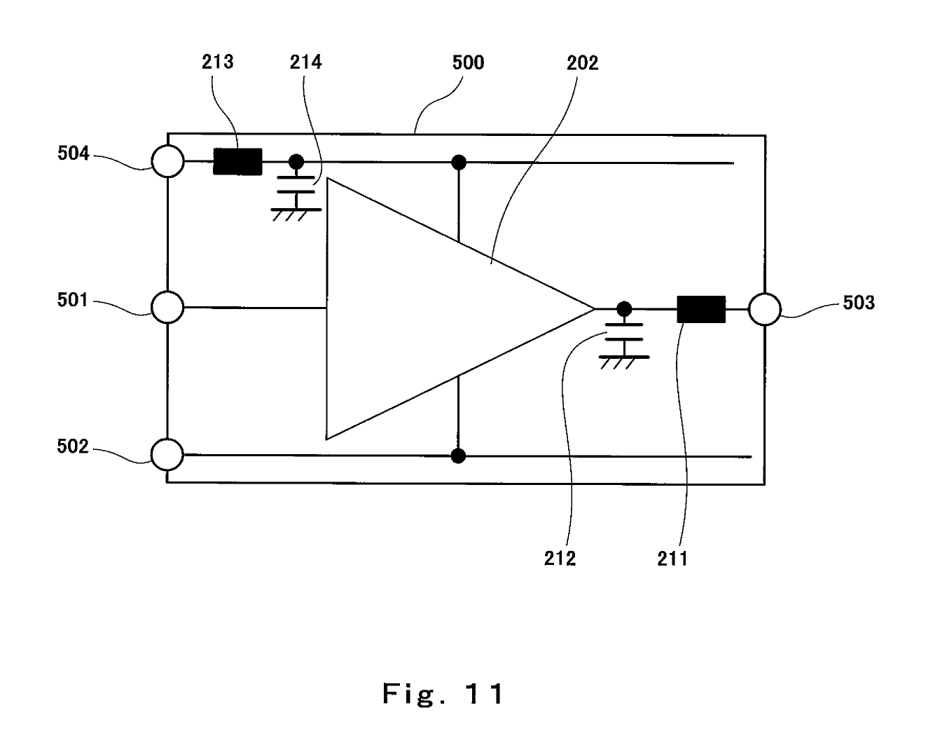

The following will discuss the countermeasure against the high frequency by configuring for the input terminal 101 the low-pass filter, which is the same as the low-pass filter configured for each of the power supply terminal and the output terminal as shown in FIG. 11. In this case, a high-frequency noise removing capacitor configured to remove the high-frequency noise is connected to an outer side or inner side of the input terminal 101. However, if the input signal of a high frequency and an extremely low voltage is input to the input terminal 101, the amplifying circuit 201 becomes a high impedance input state. In the high impedance input state, not only the high-frequency noises but also the input signals are significantly attenuated.

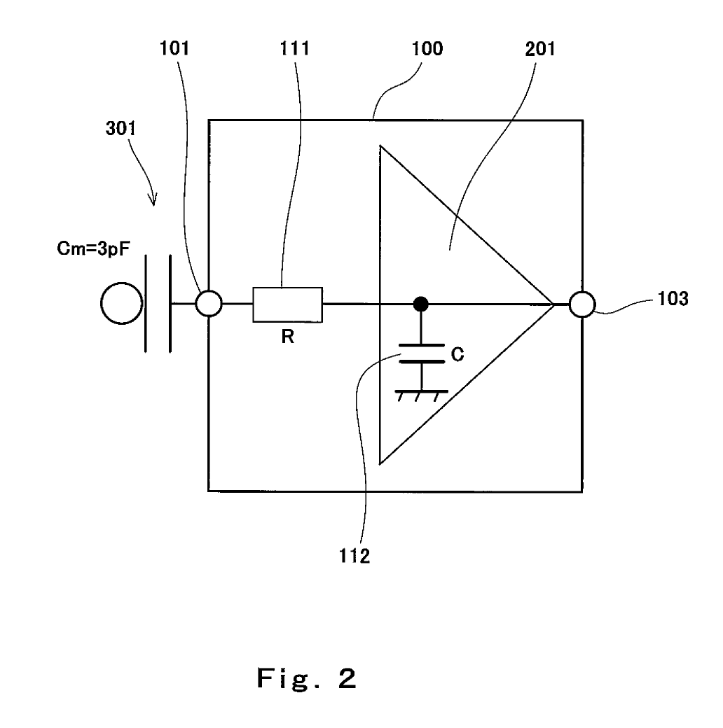

For example, in a case where the amplifier 100 with the high-frequency noise removing function is a preamplifier IC for use in the microphone module, as shown in FIG. 2, a capacitive electret element 301 is connected to the input terminal 101 and used. As shown by 3 [pF] in FIG. 2, a capacitance value of the electret element 301 is extremely small, that is, a several [pF (pico(10⁻¹²)farad] order. Therefore, if a high-frequency noise removing capacitor of a several [pF] order similar to the capacitance value of the electret element 301 is connected to the outer side of the input terminal 102 or an inner portion of the input terminal 102, the level of the input signal input to the amplifier 100 with the high-frequency noise removing function is simply attenuated up to about half by a capacitance ratio between the capacitance value of high-frequency noise removing capacitor and the capacitance value of the electret element 301 connected to the input terminal 101. On this account, the amplifier 100 cannot achieve the functions of the microphone module.

Therefore, as the required capacitance value of the high-frequency noise removing capacitor, an order significantly smaller than the capacitance value of the electret element 301 is adequate, that is, specifically, a several [fF (femto(10⁻¹⁵)farad)] order is adequate. Here, the low-pass filter 113 is formed by effectively utilizing the parasitic capacitance 112 of a several [fF] order potentially existing in the amplifying circuit 201, without separately providing the high-frequency noise removing capacitor.

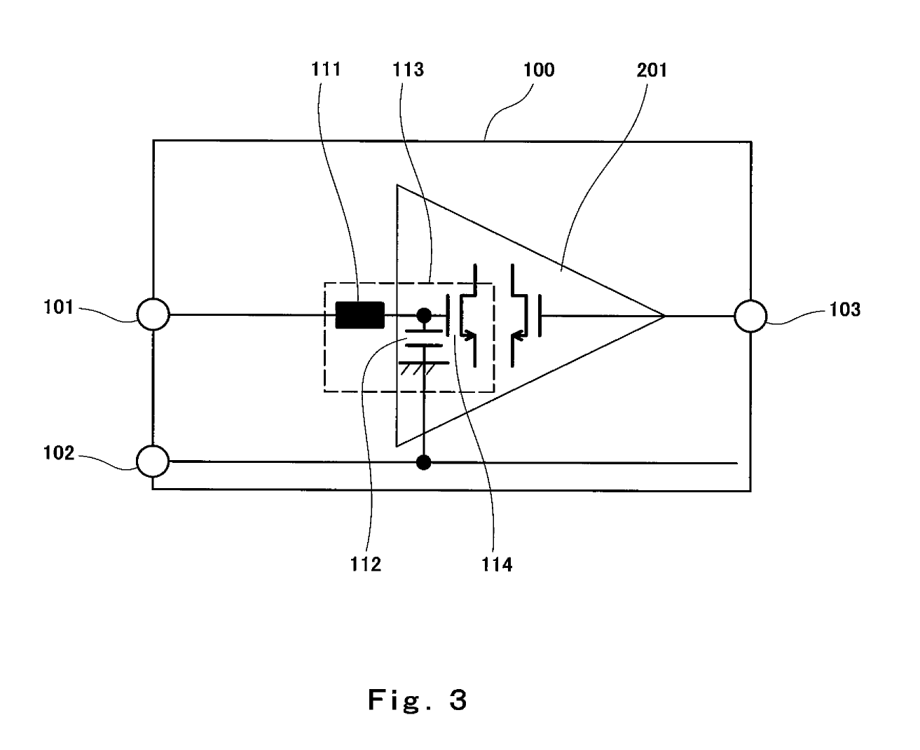

As shown in FIG. 3, as the parasitic capacitance 112, a parasitic capacitance (a capacitance between a gate and a source or a capacitance between a gate and a drain) of a MOS transistor 114 existing on the signal transmission line of the amplifying circuit 201 or a wire capacitance of the signal transmission line of the amplifying circuit 201 can be utilized.

Examples of Parameter Setting (Design) of Low-Pass Filter

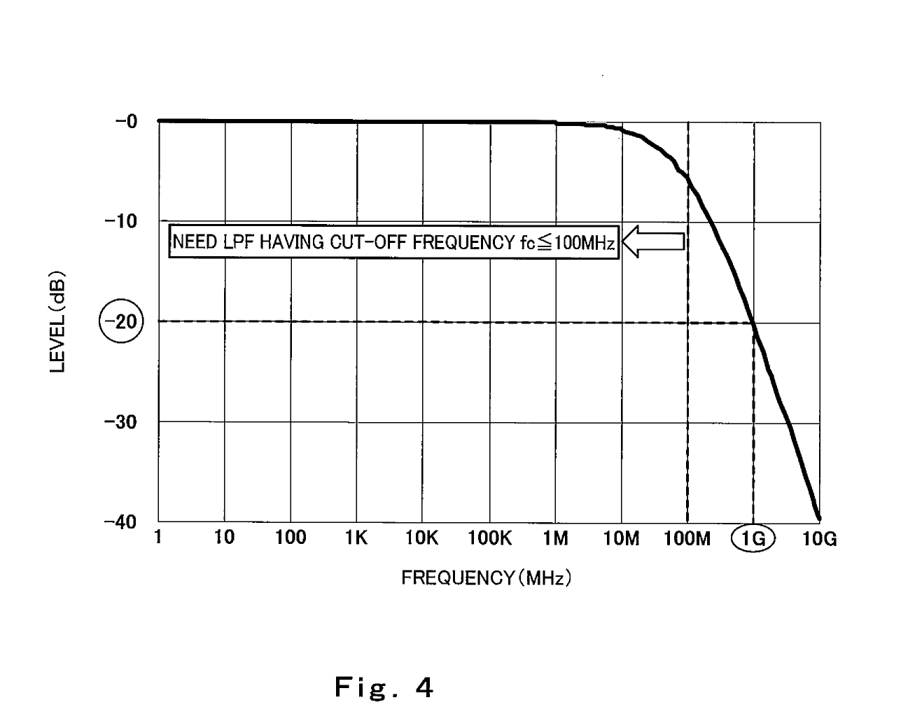

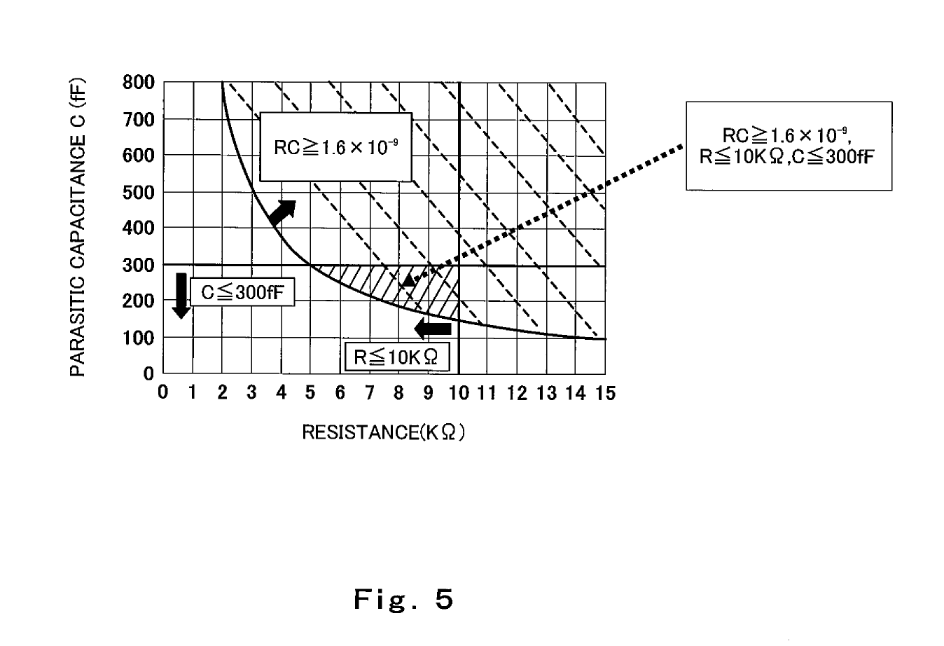

Hereinafter, examples of a parameter setting (design) of the low-pass filter 113 will be explained in reference to FIGS. 4 and 5. FIG. 4 is a graph for explaining a band of a cut-off frequency of the low-pass filter 113, the band being necessary to attenuate the high-frequency noise in a G(giga (10⁹))Hz band. FIG. 5 is a graph for explaining a relation between a resistance value R of the resistor 111 and a capacitance value C of the parasitic capacitance 112, the values being necessary to attenuate the high-frequency noise in the GHz band.

First, it is clear from the graph of FIG. 4 that the cut-off frequency fc is 100 [M(mega(10⁶))Hz] or lower in order to attenuate the high-frequency noise in the GHz band to −20 [dB] corresponding to about one tenth. Here, the audio frequency band is from about 20 [Hz] to 20 [kHz]. Therefore, when the cut-off frequency fc is 100 [MHz] or lower, the input signal of the audio frequency band is allowed to pass through the low-pass filter 113 without being attenuated.

The cut-off frequency fc of the low-pass filter 113 is typically represented by the following formula.

fc=1/(2×π×R×C) (Formula 1)

Therefore, to set the cut-off frequency fc to be 100 [MHz] or lower, the resistance value R of the resistor 111 and the capacitance value C of the parasitic capacitance 112 need to be set such that a time constant RC of the low-pass filter 113 satisfies the following formula.

RC≧1.6×10⁻⁹ (Formula 2)

Here, as shown in FIG. 3, in a case where the capacitive electret element 301 is connected to the input terminal 101, the amount of signal attenuation at an input portion of the amplifying circuit 201 becomes “Cm/(Cm+C)” times, where Cm denotes the capacitance value of the electret element 301. Here, the capacitance value Cm of the electret element 301 is typically 3 [pF]. In order that the amount of signal attenuation at the input portion of the amplifying circuit 201 is set to one tenth or less to secure the signal level, the capacitance value C of the parasitic capacitance 112 needs to satisfy the following formula.

C≦300 [fF] (Formula 3)

Meanwhile, a thermal noise generated at the resistor 111 provided in the vicinity of the input terminal 101 is amplified by the amplifying circuit 201 to be output as the noise through the output terminal 103. The thermal noise generated at the resistor 111 is proportional to the resistance value R. Moreover, the noise performance required for the microphone module is typically −80 [dB] or less, that is, a low noise performance. On this account, to secure this low noise performance, the resistance value R of the resistor 111 needs to satisfy the following formula.

R≦10 [kΩ] (Formula 4)

In accordance with the above, the resistance value R of the resistor 111 and the capacitance value C of the parasitic capacitance 112 may be set within a band (solid-line hatching portion) of a solution space satisfying Formulas 2 to 4 shown in FIG. 5.

Example of High-Frequency Noise Removal

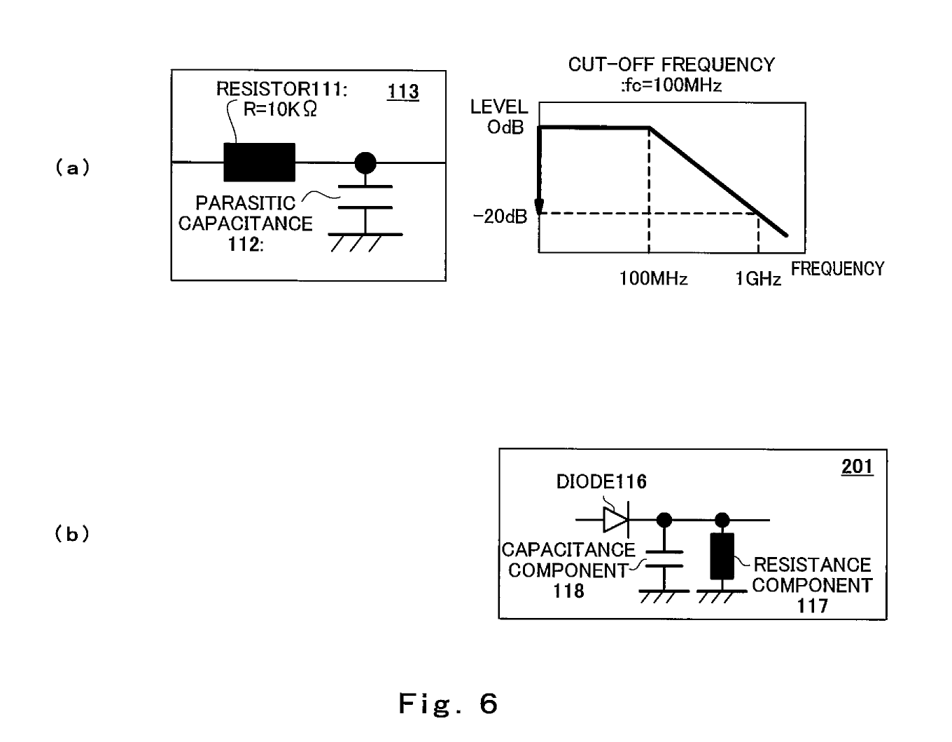

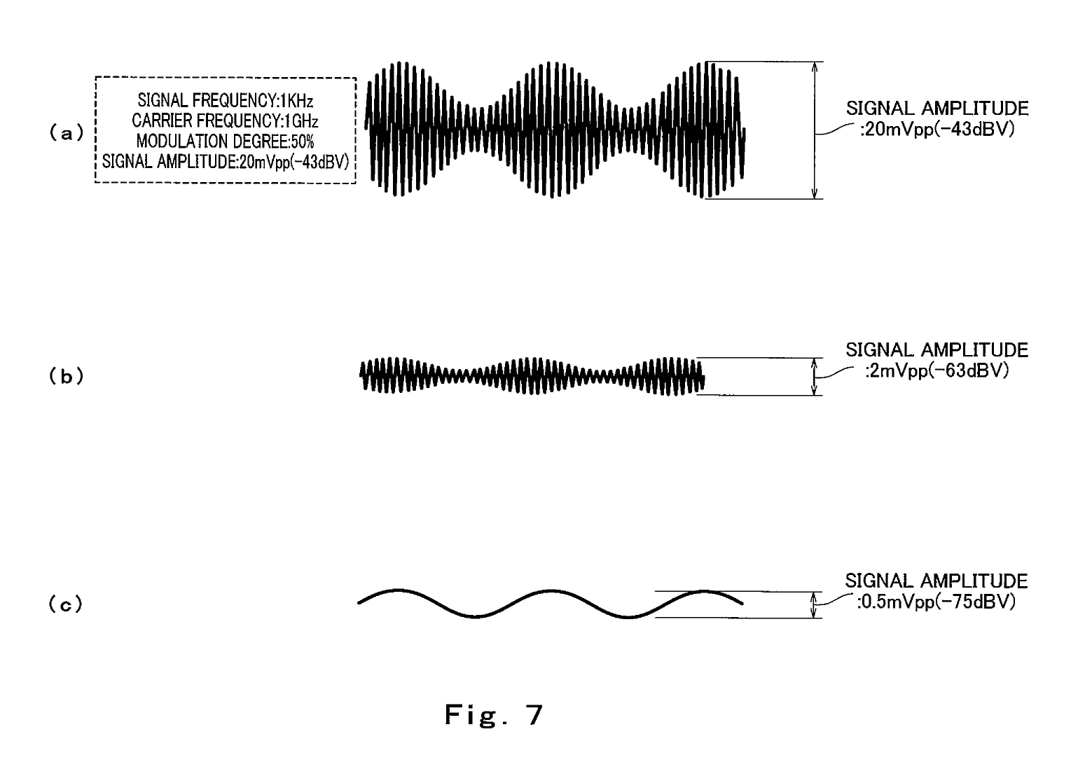

Hereinafter, an example of the high-frequency noise removal by the amplifier 100 with the high-frequency noise removing function of FIG. 1 will be explained in reference to FIGS. 6 and 7. FIGS. 6 are diagrams each showing a configuration example of the low-pass filter 113 and amplifying circuit 201 which can deal with the high-frequency noise of 1 [GHz] simulated as an amplitude modulated signal. FIGS. 7 are diagrams showing examples of waveforms of major signal of the amplifier 100 with the high-frequency noise removing function shown in FIG. 1.

As shown in FIG. 6(a), the low-pass filter 113 is configured such that the resistance value R of the resistor 111 is 10 [KΩ] and the capacitance value C of the parasitic capacitance 112 is 150 [fF]. These numerical values satisfy Formulas 2 to 4. In this case, the cut-off frequency fc of the low-pass filter 113 is 100 [MHz] as shown by the following formula.

$$\begin{matrix}fc = \frac{1}{( 2 π \times 10 [ K Ω ] \times 150 [ fF ] )} \\ = 100 [ MHz ]\end{matrix} \qquad ( Formula 5 )$$

The low-pass filter 113 designed as above can attenuate the high-frequency noise of 1 [GHz] to 1/10 (−20 dB).

As shown in FIG. 6(b), the amplifying circuit 201 includes an amplitude demodulating circuit (tuned circuit) to demodulate the below-described amplitude modulated signal simulating the high-frequency noise of 1 GHz. As shown in FIG. 6(b), an input of the amplifying circuit 201 is connected to an anode electrode of a diode 116, and a cathode electrode of the diode 116 is connected to a capacitance component 118, a resistance component 117, and an output of the amplifying circuit 201.

FIG. 7(a) is a diagram showing an example of a waveform of the amplitude modulated signal simulating the high-frequency noise of 1 [GHz]. As shown in FIG. 7(a), the signal frequency is 1 [KHz], the carrier frequency is 1 [GHz], the signal amplitude is 20 [mVpp] (−43 [dBV]), and the modulation degree is 50 [%].

FIG. 7(b) is a diagram showing an example of an output waveform of the low-pass filter 113 of FIG. 6(a) in a case where the amplitude modulated signal of FIG. 7(a) is input. As shown in FIG. 7(b), the signal amplitude of the amplitude modulated signal is attenuated from 20 [mVpp] (−43 [dBV]) up to 2 [mVpp] (−63 [dBV]).

FIG. 7(c) is a diagram showing an example of an output waveform of the amplifying circuit 201 of FIG. 6(b) in a case where the amplitude modulated signal of FIG. 7(a) is input. As shown in FIG. 7(c), the signal amplitude and signal frequency of the output waveform of the amplifying circuit 201 are respectively 0.5 [mVpp] (−75 [dBV]) and 1 [KHz].

As above, in a case where the amplitude modulated signal simulating the high-frequency noise is input to the input terminal 101, and the amplitude demodulating circuit is provided in the amplifying circuit 201, a signal generated by modulating the high-frequency noise to a frequency component in the audio frequency band is output from the output terminal 103. Therefore, to reduce the influence of the high-frequency noise and secure an adequate audio property, as in the present invention, it is necessary to prepare the countermeasure against the high-frequency noise for the input terminal 101 to adequately attenuate the amplitude component of the high-frequency noise.

### Embodiment 2

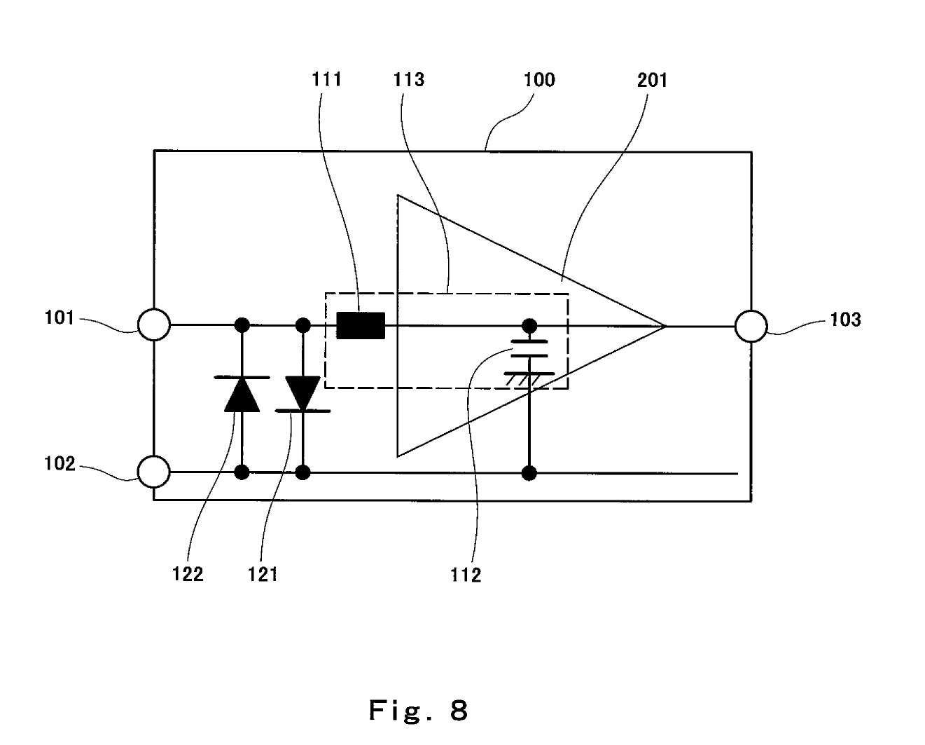

FIG. 8 is a circuit diagram showing the configuration of the amplifier with the high-frequency noise removing function according to Embodiment 2 of the present invention.

The amplifier 100 with the high-frequency noise removing function shown in FIG. 8 is different from the amplifier 100 with the high-frequency noise removing function shown in FIG. 1 in that to protect the resistor 111 from a surge voltage applied to the input terminal 101, a positive surge protective diode 121 and a negative surge protective diode 122 are connected to the signal transmission line extending between the input terminal 101 and the resistor 111.

The input terminal 101 is connected to an anode electrode of the positive surge protective diode 121, a cathode electrode of the negative surge protective diode 122, and one terminal of the resistor 111. The other terminal of the resistor 111 is connected to the input terminal of the amplifying circuit 201, and the output terminal of the amplifying circuit 201 is connected to the output terminal 103. The other end of the parasitic capacitance 112 is connected to the ground terminal 102, and the ground terminal 102 is connected to a cathode electrode of the positive surge protective diode 121 and an anode electrode of the negative surge protective diode 122.

In a case where a positive surge voltage based on the ground terminal 102 is applied to the input terminal 101, it is possible to cause a surge current to flow through the positive surge protective diode 121 to the ground terminal 102. In contrast, in a case where a negative surge voltage based on the ground terminal 102 is applied to the input terminal 101, it is possible to cause a surge current to flow through the negative surge protective diode 122 and the ground terminal 102 to the input terminal 101. As above, since the positive surge protective diode 121 and the negative surge protective diode 122 are provided between the input terminal 101 and the resistor 111, the resistor 111 can be protected from the surge voltage applied to the input terminal 101.

### Embodiment 3

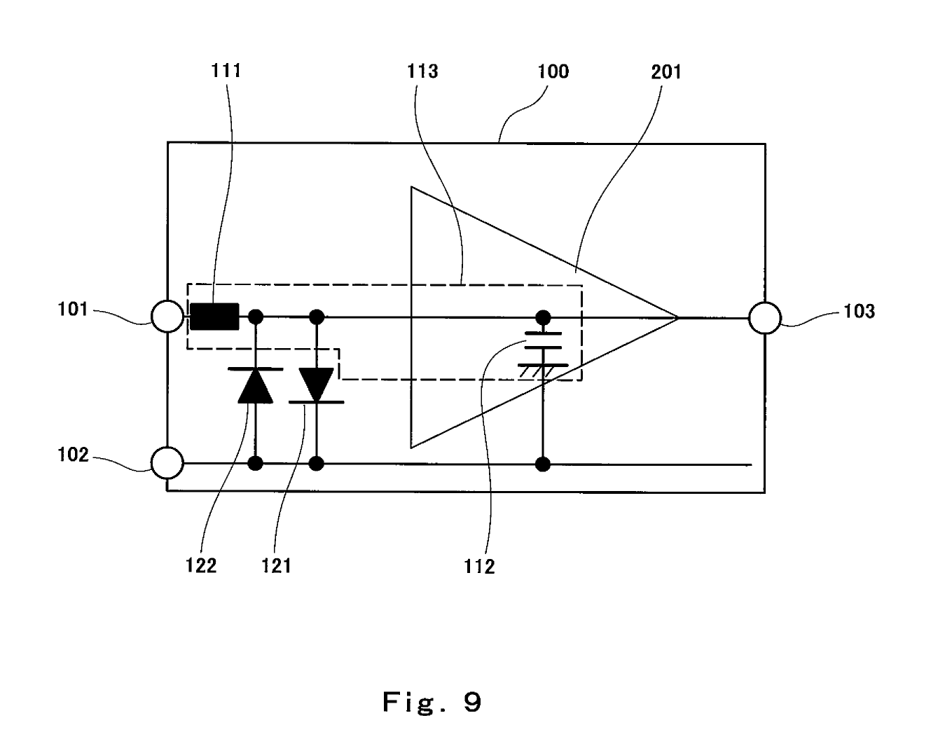

FIG. 9 is a circuit diagram showing the configuration of the amplifier with the high-frequency noise removing function according to Embodiment 3 of the present invention.

The amplifier with the high-frequency noise removing function shown in FIG. 9 is different from the amplifier 100 with the high-frequency noise removing function shown in FIG. 2 in that the resistor 111 is provided closer to the input terminal 101 than the positive surge protective diode 121 and the negative surge protective diode 122. In other words, the positive surge protective diode 121 and the negative surge protective diode 122 are connected to the signal transmission line extending between the resistor 111 and the amplifying circuit 201.

The resistance value R of the resistor 111 and the capacitance value C of the parasitic capacitance 112 need to satisfy Formula 2 above. Since the thermal noise tends to be generated by increasing the resistance value R of the resistor 111, the parasitic capacitance C needs to be increased. Here, by changing the position of the resistor 111, the capacitance values of the positive surge protective diode 121 and the negative surge protective diode 122 can be effectively utilized as the capacitance value necessary for realizing the low-pass filter 113. In other words, in a case where the capacitance value C of the parasitic capacitance 112 is inadequate, it can be compensated by the capacitance values of the positive surge protective diode 121 and the negative surge protective diode 122.

### Embodiment 4

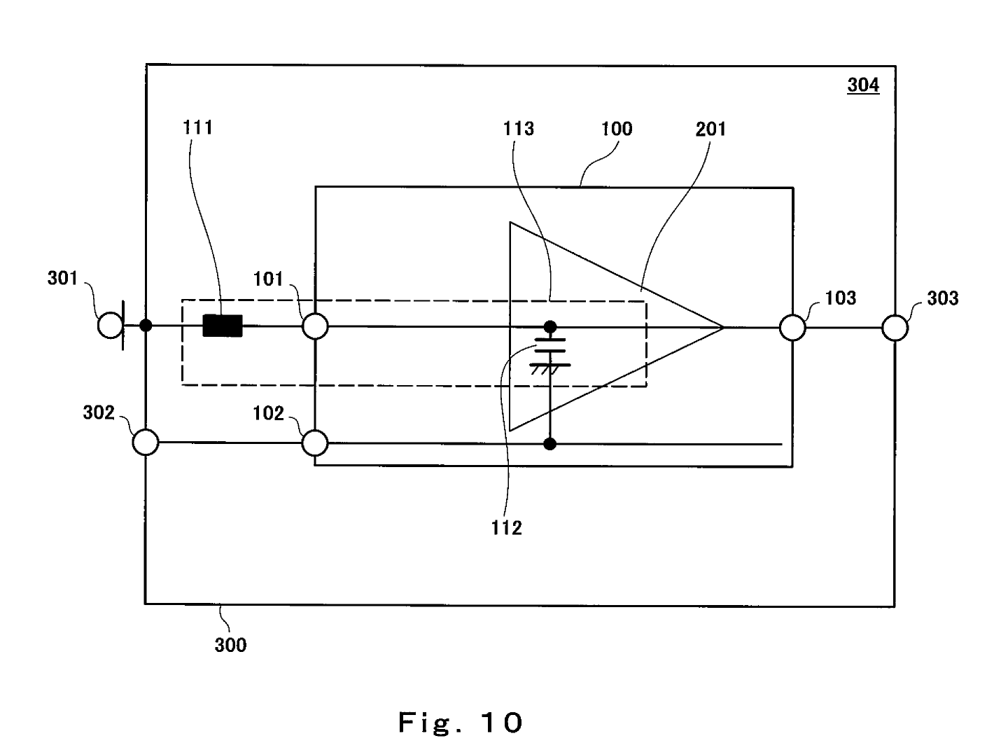

FIG. 10 is a diagram showing the configuration of a microphone module configured by using the amplifier with the high-frequency noise removing function according to Embodiment 4 of the present invention.

A microphone module 300 shown in FIG. 10 mounts the amplifier 100 with the high-frequency noise removing function integrated in a module substrate 304, and the electret element 301 is externally attached to the microphone module 300 so as to be connected to the input terminal 101 of the amplifier 100 with the high-frequency noise removing function via the resistor 111. To be specific, the resistor 111 is provided outside the amplifier 100 with the high-frequency noise removing function. Moreover, a ground terminal 302 of the module substrate 304 is connected to the ground terminal 102 of the amplifier 100 with the high-frequency noise removing function, and an output terminal 303 of the module substrate 304 is connected to the output terminal 103 of the amplifier 100 with the high-frequency noise removing function.

With the above configuration, in a case where the high-frequency noise is input to an electret element 501, it is attenuated by the low-pass filter 113 constituted by the resistor 111 and the parasitic capacitance 112 which potentially exists in the amplifier 100 with the high-frequency noise removing function, and thus, it is possible to prevent the high-frequency noise from being input to the amplifying circuit 201. As above, the microphone module having the countermeasure of the high-frequency noise removal can be realized by the low-pass filter 113 constituted by the resistor provided on the module substrate 304 and the parasitic capacitance 112 in the amplifier 100 with the high-frequency noise removing function.

In addition to the configuration of the microphone module 300 shown in FIG. 10, it may also be possible to configure a microphone module including the amplifier 100 with the high-frequency noise removing function shown in FIG. 1, 8, or 9. Further, it may also be possible to configure a sensor module by modularizing the amplifier 100 with the high-frequency noise removing function shown in FIG. 1, 8, 9, or 10 together with a capacitance type sensor, such as an acceleration sensor or a pressure sensor.

### INDUSTRIAL APPLICABILITY

The present invention is useful for a preamplifier IC incorporated in an input stage of a microphone module or a sensor module.

### REFERENCE SIGNS LIST

100 amplifier with high-frequency noise removing function

101 input terminal

102 ground terminal

103 output terminal

111 resistor

112 parasitic capacitance

113 low-pass filter

114 MOS transistor

116 diode

117 resistance component

118 capacitance component

121 positive surge protective diode

122 negative surge protective diode

201 amplifying circuit

300 microphone module

301 electret element

302 ground terminal

303 output terminal

304 module substrate

1. An amplifier with a high-frequency noise removing function comprising:
an input terminal to which an input signal is input;
a ground terminal maintained at a reference potential;
a resistor having one terminal to which the input terminal is connected;
an amplifying circuit configured to amplify and output the input signal input through the resistor; and
an output terminal through which an output signal output from the amplifying circuit is output, wherein:
the amplifying circuit includes a parasitic capacitance existing to be connected to between the other terminal of the resistor and the ground terminal;
the resistor and the parasitic capacitance constitute a low-pass filter; and
a resistance value R of the resistor and a capacitance value C of the parasitic capacitance are set so as to satisfy three formulas below:
RC≧1.6×10⁻⁹ (Formula A);
C≦300 [fF] (Formula B); and
R≦10 [kΩ] (Formula C).

2. The amplifier with the high-frequency noise removing function according to claim 1, further comprising:
a positive surge protective diode; and
a negative surge protective diode, wherein:
an anode electrode of the positive surge protective diode and a cathode electrode of the negative surge protective diode are connected to the input terminal; and
a cathode electrode of the positive surge protective diode and an anode electrode of the negative surge protective diode are connected to the ground terminal.

3. The amplifier with the high-frequency noise removing function according to claim 1, further comprising:
a positive surge protective diode; and
a negative surge protective diode, wherein:
an anode electrode of the positive surge protective diode and a cathode electrode of the negative surge protective diode are connected to said other terminal of the resistor or an input terminal of the amplifying circuit; and
a cathode electrode of the positive surge protective diode and an anode electrode of the negative surge protective diode are connected to the ground terminal.

4. (canceled)

5. A microphone module comprising the amplifier with the high-frequency noise removing function according to claim 1.

6. A sensor module comprising the amplifier with the high-frequency noise removing function according to claim 1.
